(19) United States
(12) Patent Application Publication
(10) Pub. No.: US 2015/0287639 A1
(43) Pub. Date: Oct. 8, 2015

(54) SEMICONDUCTOR CHIP, BOARD HAVING THE SAME MOUNTED THEREON, AND METHOD OF CUTTING SEMICONDUCTOR WAFER

(71) Applicant: Samsung Electro-Mechanics Co., Ltd., Suwon-Si (KR)

(72) Inventors: Yong Hui JOO, Suwon-Si (KR); Jung Mi Oh, Suwon-Si (KR)

(73) Assignee: Samsung Electro-Mechanics Co., Ltd., Suwon-Si (KR)

(21) Appl. No.: 14/497,294

(22) Filed: Sep. 25, 2014

(30) Foreign Application Priority Data
Apr. 2, 2014 (KR) 10-2014-0039079

(51) Int. Cl. H01L 21/78; H01L 29/06; H01L 23/544

(52) U.S. Cl. CPC H01L 21/78; H01L 23/544; H01L 29/0657

(57) ABSTRACT

A semiconductor chip may include: a semiconductor body having scribe lines formed in both end surfaces thereof; and a metal layer formed on a lower surface of the semiconductor body and the scribe lines. An upper surface of the semiconductor body may have a width greater than that of the lower surface thereof. The semiconductor chip may be stably mounted on a printed circuit board, such that quality and a yield may be improved in a wire-bonding process between the semiconductor chip and the printed circuit board.

### CROSS-REFERENCE TO RELATED APPLICATION

This application claims the benefit of Korean Patent Application No. 10-2014-0039079 filed on Apr. 2, 2014, with the Korean Intellectual Property Office, the disclosure of which is incorporated herein by reference.

### BACKGROUND

The present disclosure relates to a semiconductor chip, a board having the same mounted thereon, and a method of cutting a semiconductor wafer.

Semiconductor chips are commonly manufactured by depositing a metal layer on a lower surface of a semiconductor wafer having an integrated circuit formed on a surface thereof and cutting the semiconductor wafer having the metal deposited on the lower surface thereof using a diamond cutting blade or a laser.

At the time of cutting the semiconductor wafer, a chipping defect may occur, and excessive chipping weakens bonding strength after soldering and may cause a reliability problem such as a progressive cracking, or the like.

The semiconductor chip obtained after cutting the semiconductor wafer is mounted on a printed circuit board using a soldering process.

After the soldering process, a tilting phenomenon in which the semiconductor chip is tilted on the printed circuit board due to surface tension of a solder may occur.

When such a tilting phenomenon occurs, it may be difficult to wire-bond the semiconductor chip and the printed circuit board to each other. Therefore, quality and a yield of a finished product may be decreased.

Therefore, a method of cutting a semiconductor wafer capable of decreasing chipping defects and suppressing a tilting phenomenon in order to improve bonding properties of a solder is required.

The following Related Art Documents (Patent Documents 1 and 2) disclose a method of cutting a semiconductor wafer.

### RELATED ART DOCUMENTS

(Patent Document 1) Korean Patent Laid-Open Publication No. 10-2009-0046174
(Patent Document 2) Japanese Patent Laid-Open Publication No. 2006-24586

### SUMMARY

An exemplary embodiment in the present disclosure may provide a semiconductor chip having improved bonding reliability, a board having the same mounted thereon, and a method of cutting a semiconductor wafer capable of ensuring good quality.

According to an exemplary embodiment in the present disclosure, a semiconductor chip may include: a semiconductor body having scribe lines formed in both end surfaces thereof; and a metal layer formed on a lower surface of the semiconductor body and the scribe lines, wherein an upper surface of the semiconductor body has a width greater than that of the lower surface thereof.

The scribe lines may be formed vertically from the lower surface of the semiconductor body.

A ratio of a depth of the scribe lines to an overall thickness of the semiconductor body may be in a range of 0.3 to 0.7.

The scribe lines may be formed from the lower surface of the semiconductor body into the semiconductor body.

The metal layer may have a thickness of 5 μm or less.

According to an exemplary embodiment in the present disclosure, a board having a semiconductor chip mounted thereon may include: a printed circuit board; a semiconductor chip including a semiconductor body having scribe lines formed in both end surfaces thereof and a metal layer formed on a lower surface of the semiconductor body and the scribe lines; and a solder bonding part formed on a surface of the printed circuit board and bonded to the metal layer, wherein an upper surface of the semiconductor body has a width greater than that of the lower surface thereof.

In the case that a mounting angle of the semiconductor chip on the printed circuit board when the printed circuit board and the semiconductor chip are in parallel with each other is 0°, a mounting angle of the semiconductor chip on the printed circuit board may be 1.5° or less.

A ratio of a depth of the scribe lines to an overall thickness of the semiconductor body may be in a range of 0.3 to 0.7.

The scribe lines may be formed from the lower surface of the semiconductor body into the semiconductor body.

The metal layer may have a thickness of 5 μm or less.

According to an exemplary embodiment in the present disclosure, a method of cutting a semiconductor wafer may include: preparing a semiconductor wafer including scribe regions and semiconductor chip regions; forming first scribe lines from a lower surface of the semiconductor wafer into the scribe regions; forming a metal layer on the lower surface of the semiconductor wafer and the first scribe lines; and forming second scribe lines from an upper surface of the semiconductor wafer into the scribe regions to cut the semiconductor wafer into a plurality of semiconductor chips.

In the case that a width of the first scribe lines is W1 and a width of the second scribe lines is W2, W1>W2 may be satisfied.

In the case that a thickness of the semiconductor wafer is Ta and a depth of the first scribe lines is T1, a ratio (T1/Ta) of the depth of the first scribe lines to the thickness of the semiconductor wafer may be in a range of 0.3 to 0.7.

The first scribe lines may be formed from the lower surface of the semiconductor wafer into the semiconductor chip region.

The metal layer may have a thickness of 5 μm or less.

### BRIEF DESCRIPTION OF DRAWINGS

The above and other aspects, features and other advantages in the present disclosure will be more clearly understood from the following detailed description taken in conjunction with the accompanying drawings, in which:

FIG. 1 is a cross-sectional view of a semiconductor chip according to an exemplary embodiment in the present disclosure;

FIG. 2 is a cross-sectional view schematically illustrating a board having a semiconductor chip mounted thereon according to an exemplary embodiment in the present disclosure;

FIG. 3A is a scanning electron microscope (SEM) photograph illustrating a shape of a cross section of a board having a semiconductor chip mounted thereon according to the related art, and FIG. 3B is an SEM photograph illustrating a shape of a cross section of the board having a semiconductor chip mounted thereon according to an exemplary embodiment in the present disclosure;

FIG. 4 is a cross-sectional view schematically illustrating a board having a semiconductor chip mounted thereon according to another exemplary embodiment in the present disclosure;

FIG. 5 is a plan view of a semiconductor wafer including scribe regions and semiconductor chip regions according to an exemplary embodiment in the present disclosure;

FIGS. 6A through 6D are diagrams illustrating a method of cutting a semiconductor wafer according to an exemplary embodiment in the present disclosure;

FIG. 7 is a plan view of a semiconductor wafer in which first scribe lines are formed according to an exemplary embodiment in the present disclosure;

FIGS. 8A through 8D are diagrams illustrating a method of cutting a semiconductor wafer according to another exemplary embodiment in the present disclosure;

FIG. 9 is a plan view of a semiconductor wafer in which first scribe lines are formed according to another exemplary embodiment in the present disclosure; and

FIG. 10A is a graph illustrating a distribution of mounting angles of the semiconductor chip according to the related art on a board, and FIG. 10B is a graph illustrating a distribution of mounting angles of the semiconductor chip according to an exemplary embodiment in the present disclosure on a board.

### DETAILED DESCRIPTION

Hereinafter, embodiments in the present disclosure will be described in detail with reference to the accompanying drawings.

The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

In the present exemplary embodiment, for convenience of explanation, both end surfaces of a semiconductor body refer to surfaces on which scribe lines are formed in a length direction of the semiconductor body, both side surfaces thereof refer to surfaces vertically intersecting with both end surfaces, and upper and lower surfaces thereof refer to surfaces of the semiconductor body in a thickness direction.

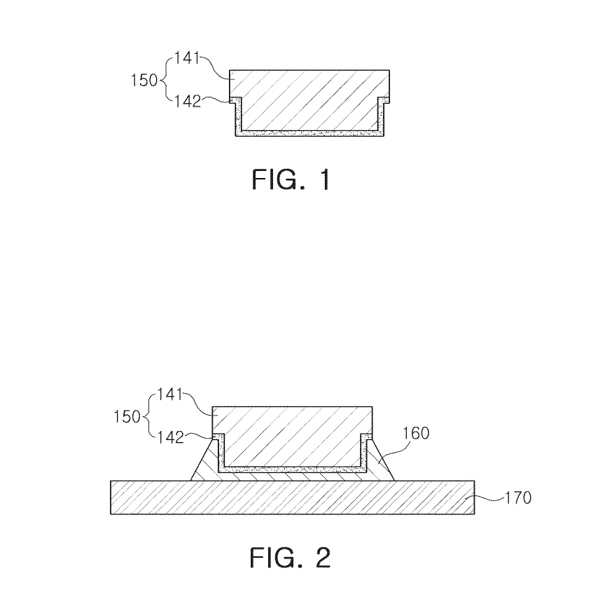

FIG. 1 is a cross-sectional view of a semiconductor chip according to an exemplary embodiment in the present disclosure.

Referring to FIG. 1, a semiconductor chip 150 according to an exemplary embodiment in the present disclosure may include a semiconductor body 141 having scribe lines formed in both end surfaces thereof; and a metal layer 142 formed on a lower surface of the semiconductor body and the scribe lines, wherein an upper surface of the semiconductor body 141 has a width greater than that of the lower surface thereof.

The semiconductor body 141 may have the scribe lines formed in both end surfaces thereof and have integrated circuits formed on an upper surface thereof.

The scribe lines may be formed vertically from the lower surface of the semiconductor body 141.

A ratio of a depth of the scribe lines to an overall thickness of the semiconductor body 141 may be in a range of 0.3 to 0.7.

When the ratio of the depth of the scribe lines to the overall thickness of the semiconductor body is in the range of 0.3 to 0.7, bonding reliability between the semiconductor chip and a solder may be improved at the time of the bonding between the semiconductor chip and the solder.

In the case in which the ratio of the depth of the scribe lines to the overall thickness of the semiconductor body is less than 0.3, the bonding reliability between the semiconductor chip and the solder may be low, and in the case in which the ratio of the depth of the scribe lines to the overall thickness of the semiconductor body exceeds 0.7, an excessive solder fillet may be formed on a side surface of the semiconductor body at the time of the bonding between the semiconductor chip and the solder, such that non-uniformity of a size of the solder fillet may be caused.

The semiconductor body 141 may have the scribe lines formed from the lower surface thereof thereinto.

The number of scribe lines formed from the lower surface of the semiconductor body 141 into the semiconductor body 141 may be one or more.

When the scribe lines are formed into the semiconductor body, a bonding area between the semiconductor chip and the solder may be increased. Therefore, bonding strength may be increased, and reliability badness for a solder crack may be suppressed.

The semiconductor body 141 may have a T-shaped cross section in which the upper surface thereof has a width greater than that of the lower surface thereof by the scribe lines.

The metal layer 142 may be formed on the lower surface of the semiconductor body 141 and the scribe lines.

The metal layer 142 may be formed in order to form a bond between the semiconductor chip 150 and the solder.

In the case in which the scribe lines are formed from the lower surface of the semiconductor body 141 into the semiconductor body 141, the metal layer 142 may be formed up to the scribe lines and an inner portion of the semiconductor body 141.

The metal layer 142 may contain a material having excellent electrical conductivity, for example, at least one selected from a group consisting of copper (Cu), nickel (Ni), tin (Sn), silver (Ag), and gold (Au). However, the present disclosure is not limited thereto.

The metal layer 142 may have a thickness of 5 μm or less so as to sufficiently cover a depth of the scribe lines.

That is, when the metal layer is formed on the lower surface of the semiconductor body and the scribe lines formed in the end surfaces of the semiconductor body as in the present exemplary embodiment, a thickness of a solder bonding part may be easily adjusted at the time of the bonding between the semiconductor chip and the solder, and a tilting phenomenon in which the semiconductor chip is tilted on a printed circuit board due to surface tension of the solder may be prevented.

FIG. 2 is a cross-sectional view schematically illustrating a board having a semiconductor chip mounted thereon according to an exemplary embodiment in the present disclosure.

Referring to FIG. 2, a board having a semiconductor chip mounted thereon according to an exemplary embodiment in the present disclosure may include a printed circuit board 170; the semiconductor chip 150 including the semiconductor body 141 having the scribe lines formed in both end surfaces thereof and the metal layer 142 formed on the lower surface of the semiconductor body 141 and the scribe lines; and a solder bonding part 160 formed on a surface of the printed circuit board 170 and bonded to the metal layer 142, wherein the upper surface of the semiconductor body 141 has a width greater than that of the lower surface thereof.

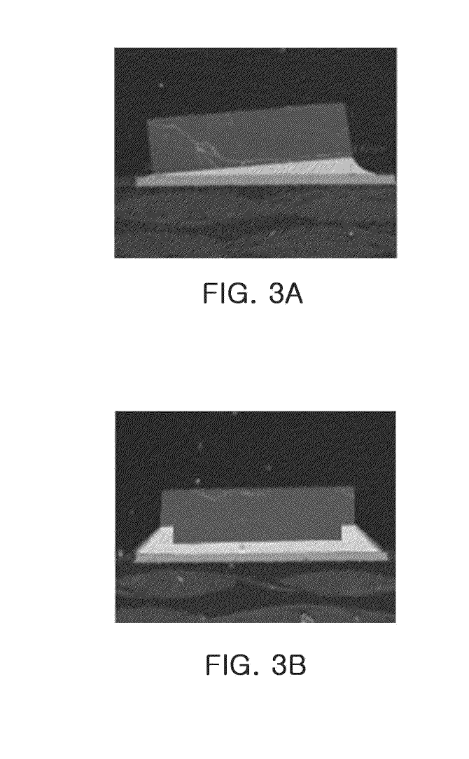

FIG. 3A is a scanning electron microscope (SEM) photograph illustrating a shape of a cross section of a board having a semiconductor chip mounted thereon according to the related art, and FIG. 3B is an SEM photograph illustrating a shape of a cross section of the board having a semiconductor chip mounted thereon according to an exemplary embodiment in the present disclosure.

Referring to FIG. 3A, as described in background, the tilting phenomenon in which the semiconductor chip is tilted on the printed circuit board due to the surface tension of the solder at the time of the bonding between the semiconductor chip and the solder may occur.

When the tilting phenomenon occurs, it may be difficult to wire-bond the semiconductor chip and the printed circuit board to each other. Therefore, quality and yield of a finished product may be decreased.

In order to solve this problem, in the semiconductor chip 150 according to an exemplary embodiment in the present disclosure, the upper surface of the semiconductor body 141 may have the width greater than that of the lower surface thereof, and the metal layer 142 may be formed on the lower surface of the semiconductor body 141 and the scribe lines.

Referring to FIG. 3B, a thickness of the solder bonding part 160 may be easily adjusted at the time of the bonding between the semiconductor chip 150 and the solder, and the tilting phenomenon in which the semiconductor chip 150 is tilted due to the surface tension of the solder may be prevented.

A gradient of mounting angles of the semiconductor chip may be smaller than that of mounting angles of the semiconductor chip according to the related art, and a distribution of the mounting angles of the semiconductor chip may be more excellent than that of that of mounting angles of the semiconductor chip according to the related art.

In the case that a mounting angle of the semiconductor chip 150 on the printed circuit board 170 when the printed circuit board 170 and the semiconductor chip 150 are in parallel with each other is 0°, a mounting angle of the semiconductor chip 150 on the printed circuit board 170 may be 1.5° or less.

The semiconductor chip 150 may be mounted on the printed circuit board at a mounting angle close to 0° at the time of being mounted on the printed circuit board. Therefore, quality and a yield in a wire-bonding process after the semiconductor chip is mounted on the printed circuit board may be increased.

In addition, since bonding reliability between the semiconductor chip and the solder may be excellent due to the semiconductor chip having a T-shape, stability in mounting the semiconductor chip on the printed circuit board may be secured.

The ratio of the depth of the scribe lines to the overall thickness of the semiconductor body 150 may be in the range of 0.3 to 0.7.

When the ratio of the depth of the scribe lines to the overall thickness of the semiconductor body 150 is in the range of 0.3 to 0.7, reliability of the solder bonding part may be improved.

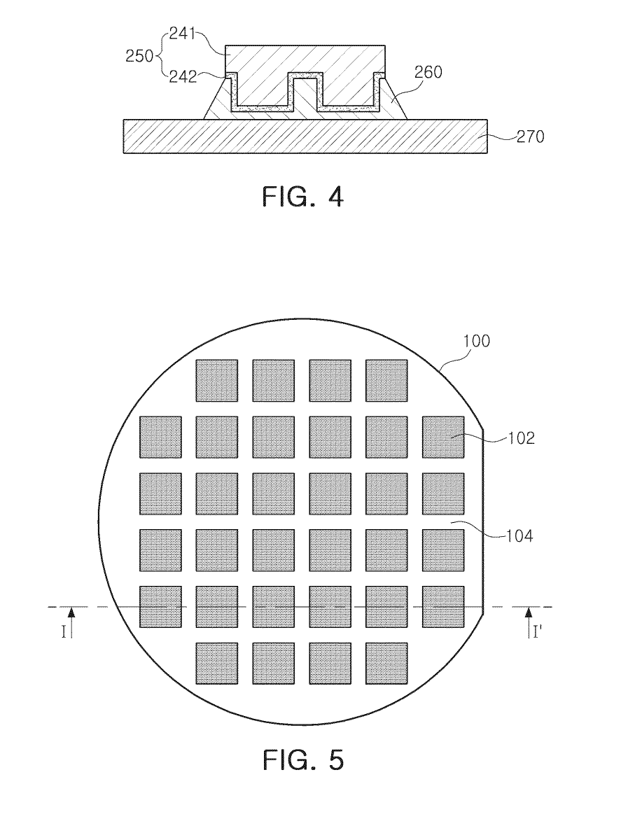

FIG. 4 is a cross-sectional view schematically illustrating a board having a semiconductor chip mounted thereon according to another exemplary embodiment in the present disclosure.

A description for components that are the same as the components shown in FIG. 2 among components shown in FIG. 4 will be omitted.

Referring to FIG. 4, the semiconductor body 241 may have the scribe lines formed from the lower surface thereof thereinto.

The number of scribe lines formed from the lower surface of the semiconductor body 241 into the semiconductor body 241 may be one or more.

When the scribe lines are formed into the semiconductor body, a bonding area between the semiconductor chip and the solder may be increased. Therefore, bonding strength may be increased, and reliability badness for a solder crack may be suppressed.

The metal layer 242 may be formed up to the scribe lines and an inner portion of the semiconductor body 241.

As described above, in the semiconductor chip 250, a thickness of the solder bonding part 660 may be easily adjusted, and the tilting phenomenon in which the semiconductor chip 250 is tilted due to the surface tension of the solder may be prevented, such that bonding reliability between the semiconductor chip and the solder may be improved.

Next, a method of cutting a semiconductor wafer for obtaining the semiconductor chip according to an exemplary embodiment in the present disclosure will be described.

FIG. 5 is a plan view of a semiconductor wafer including scribe regions and semiconductor chip regions according to an exemplary embodiment in the present disclosure.

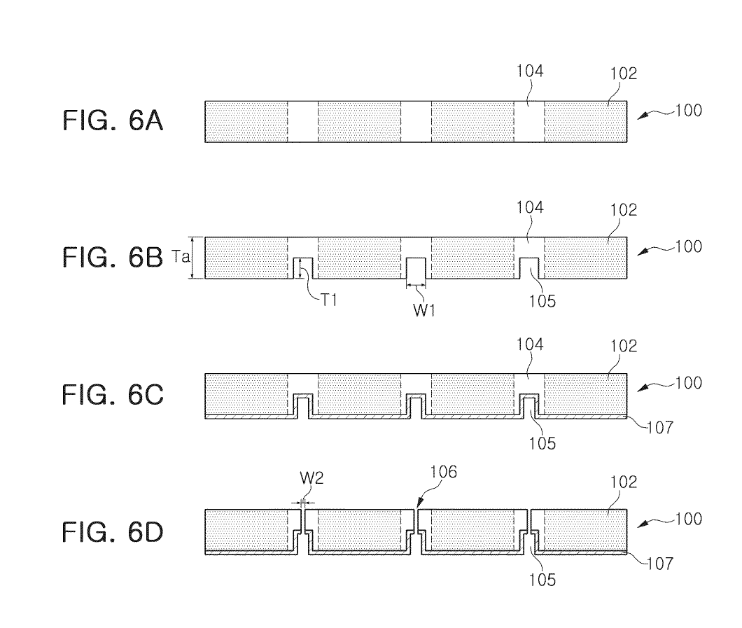

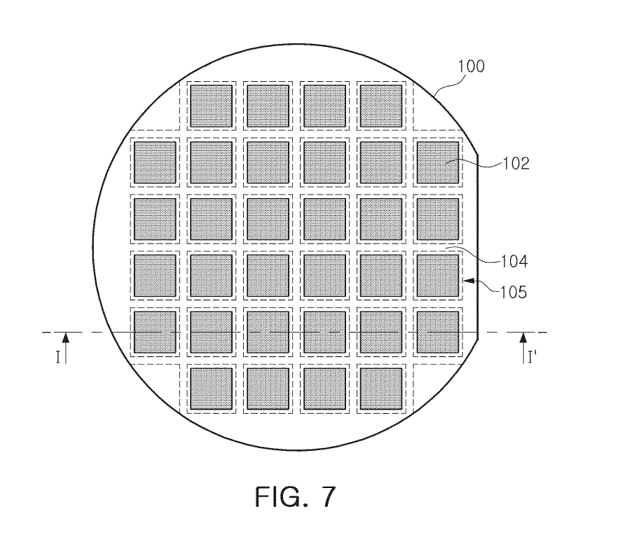

FIGS. 6A through 6D are diagrams illustrating a method of cutting a semiconductor wafer according to an exemplary embodiment in the present disclosure; and FIG. 7 is a plan view of a semiconductor wafer in which first scribe lines are formed according to an exemplary embodiment in the present disclosure.

FIG. 6A is a cross-sectional view taken along line I-I′ of FIG. 5, and FIG. 6C is a cross-sectional view taken along line I-I′ of FIG. 7.

Referring to FIG. 6, a method of cutting a semiconductor wafer according to an exemplary embodiment in the present disclosure may include (a) preparing a semiconductor wafer 100 including scribe regions 104 and semiconductor chip regions 102; (b) forming first scribe lines 105 from a lower surface of the semiconductor wafer 100 into the scribe regions 104; (c) forming a metal layer 107 on the lower surface of the semiconductor wafer 100 and the first scribe lines 105; and (d) forming second scribe lines 106 from an upper surface of the semiconductor wafer 100 into the scribe regions 104 to cut the semiconductor wafer 100 into a plurality of semiconductor chips 150.

First, in the preparing of the semiconductor wafer, the semiconductor wafer 100 including the scribe regions 104 and the semiconductor chip regions 102 may be prepared.

The semiconductor wafer 100 according to an exemplary embodiment in the present disclosure may include the scribe regions 104 and the semiconductor chip regions 102.

The semiconductor chip region 102 may correspond to a portion having an integrated circuit formed on an upper surface of the semiconductor wafer 100, and the scribe region 104 may correspond to a portion cut in order to separate the semiconductor wafer 100 into unit semiconductor chips.

Next, the first scribe lines 105 may be formed from the lower surface of the semiconductor wafer 100 into the scribe regions 104.

The first scribe lines 105 may be formed by a diamond blade cutting method or a laser cutting method.

In addition, a width of the first scribe lines 105 may be smaller than that of the scribe region 104. In detail, a width of the first scribe lines 105 may be 300 μm or less.

Referring to FIG. 7, the first scribe lines 105 may enclose the semiconductor chip regions 102 along the scribe regions 104.

In the case that a thickness of the semiconductor wafer 100 is Ta and a depth of the first scribe lines 105 is T1, a ratio (T1/Ta) of the depth of the first scribe lines to the thickness of the semiconductor wafer may be in a range of 0.3 to 0.7 (See FIG. 6B).

The ratio (T1/Ta) of the depth of the first scribe lines to the thickness of the semiconductor wafer is in the range of 0.3 to 0.7, such that the occurrence of chipping at the time of cutting the semiconductor wafer may be significantly decreased, whereby a semiconductor chip having good quality may be manufactured.

In the case in which the ratio (T1/Ta) of the depth of the first scribe lines to the thickness of the semiconductor wafer is less than 0.3, a defect such as the chipping may excessively occur on a surface of the semiconductor chip at the time of cutting the semiconductor wafer.

In the case in which the ratio (T1/Ta) of the depth of the first scribe lines to the thickness of the semiconductor wafer exceeds 0.7, the depth of the first scribe lines may be increased, such that the semiconductor wafer may be vulnerable to impact due to the first scribe lines. Therefore, there may be a risk that the semiconductor wafer will be broken during post-processing, and excessive chipping may occur on the surface of the semiconductor wafer.

Next, the metal layer 107 may be formed on the lower surface of the semiconductor wafer 100 and the first scribe lines 105.

Referring to FIG. 6C, the metal layer 107 may be formed on the lower surface of the semiconductor wafer 100 and the first scribe lines 105 so as to be bonded to the solder bonding part at the time of mounting the semiconductor chip.

In the case in which the metal layer 107 is formed after the first scribe lines 105 are formed, a region in which the metal layer is formed may be increased as compared to the case in which the metal layer is only formed on the lower surface of the semiconductor wafer.

Therefore, the metal layer may be formed up to the side surface of the semiconductor chip obtained by cutting the semiconductor wafer by a post-process.

When the metal layer is formed up to the side surface of the semiconductor chip, the tilting phenomenon in which the semiconductor chip is tilted due to the surface tension of the solder at the time of the bonding between the semiconductor chip and the solder may be prevented. Therefore, quality of the bonding between the semiconductor chip and the solder may be improved.

The metal layer 107 may be formed of a material having excellent electrical conductivity, for example, at least one selected from a group consisting of copper (Cu), nickel (Ni), tin (Sn), silver (Ag), and gold (Au). However, the present disclosure is not limited thereto.

Here, the metal layer 107 may be formed by a general method, for example, one of an applying method, a plating method, a depositing method, a sputtering method, and the like. However, the present disclosure is not limited thereto.

The metal layer 107 may be formed to have a thickness of 5 μm or less.

The metal layer 107 may sufficiently cover the first scribe lines 105.

Next, the second scribe lines 106 may be formed from the upper surface of the semiconductor wafer 100 into the scribe regions 104 to cut the semiconductor wafer 100 into the plurality of semiconductor chips 150.

Referring to FIG. 6D, after the metal layer is formed, the second scribe lines may be formed from the upper surface of the semiconductor wafer into the scribe regions in order to cut the semiconductor wafer into the plurality of semiconductor chips.

The second scribe lines 106 may be formed by a diamond blade cutting method or a laser cutting method.

The second scribe lines 106 may enclose the semiconductor chip regions along the scribe regions.

The second scribe lines 106 may meet the first scribe lines 105, but are not limited thereto.

The first scribe lines 105 may prevent chipping or cracking occurring in a process of forming the second scribe lines 106. Therefore, the semiconductor chip having good quality may be manufactured.

In the case in which the first and second scribe lines 105 and 106 are formed by the diamond blade cutting method, a diamond blade for forming the second scribe lines 106 may have a width narrower than that of a diamond blade for forming the first scribe lines 105.

Therefore, in the case that a width of the first scribe lines 105 is W1 and a width of the second scribe lines 106 is W2, W1>W2 may be satisfied.

When the above Equation: W1>W2 is satisfied, the semiconductor chip obtained by cutting the semiconductor wafer may have the T-shaped cross section in which the upper surface thereof has a width greater than that of the lower surface thereof.

Since the semiconductor chip has the T-shaped cross section, the thickness of the solder bonding part may be easily adjusted at the time of the bonding between the semiconductor chip and the solder, and the tilting phenomenon in which the semiconductor chip is tilted due to the surface tension of the solder may be prevented.

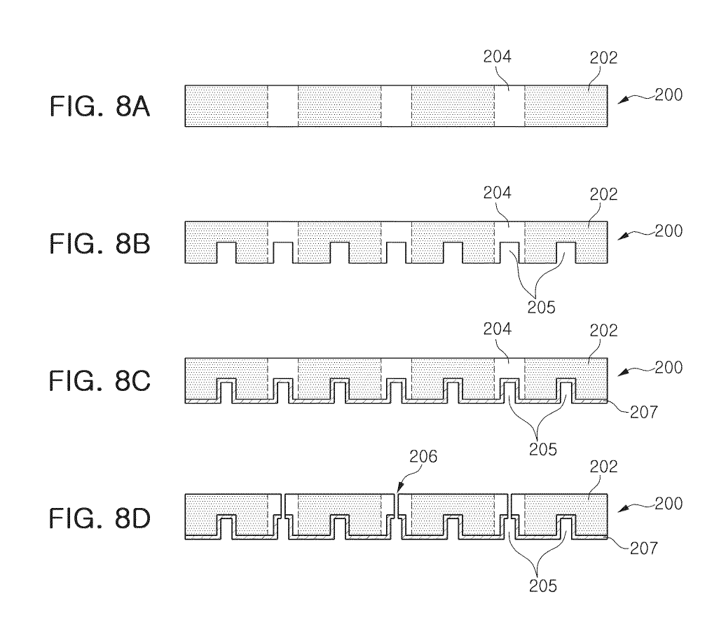

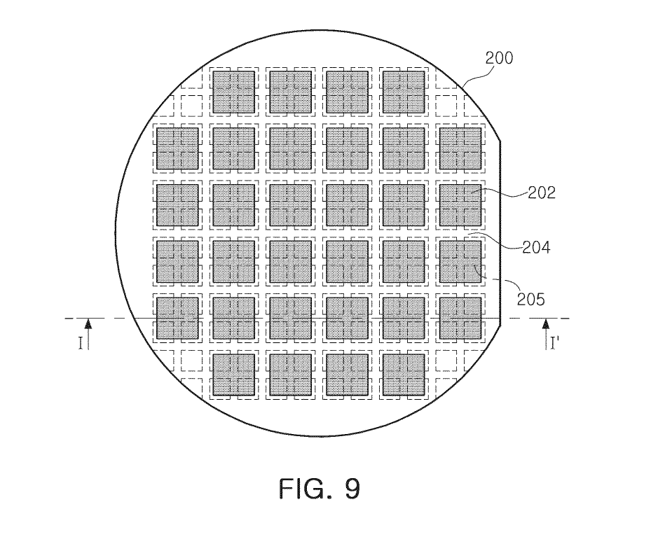

FIGS. 8A through 8D are diagrams illustrating a method of cutting a semiconductor wafer according to another exemplary embodiment in the present disclosure. FIG. 9 is a plan view of a semiconductor wafer in which first scribe lines are formed according to another exemplary embodiment in the present disclosure.

FIG. 8A is a cross-sectional view taken along line I-I′ of FIG. 5, and FIG. 8C is a cross-sectional view taken along line I-I′ of FIG. 9.

A description for components that are the same as the components shown in FIG. 6 among components shown in FIG. 8 will be omitted.

Referring to FIG. 8B, the first scribe lines 205 maybe formed from the lower surface of the semiconductor wafer 200 into the semiconductor chip regions 202.

Referring to FIG. 9, the first scribe lines 205 may enclose the semiconductor chip regions 202 along the scribe regions 204 and be, at the same time, formed in the semiconductor chip regions 202.

In the case in which the metal layer 207 is formed after the first scribe lines 205 are formed in the semiconductor chip regions, a region in which the metal layer is formed may be increased as compared to the case in which the metal layer is only formed on the lower surface of the semiconductor wafer.

That is, the metal layer may be formed from the semiconductor chip obtained by a process of cutting the semiconductor wafer, which is a post-process, up to the side surface and the inner portion of the semiconductor body.

As described above, when the metal layer is formed up to the side surface of the semiconductor body and the inner portion of the semiconductor body, the tilting phenomenon in which the semiconductor chip is tilted due to the surface tension of the solder at the time of the bonding between the semiconductor chip and the solder may be prevented, such that the quality of the bonding between the semiconductor chip and the solder may be improved.

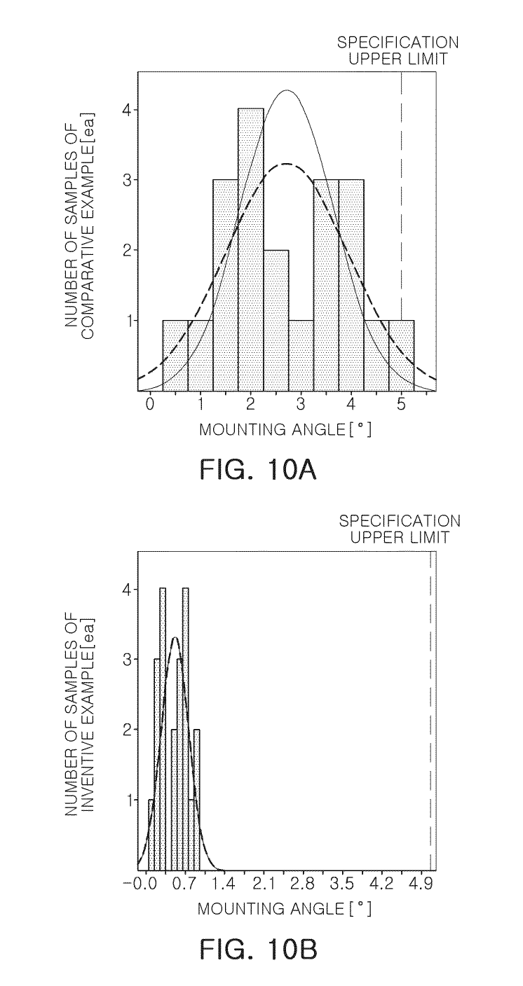

FIG. 10A is a graph illustrating a distribution of mounting angles of the semiconductor chip according to the related art on a board, and FIG. 10B is a graph illustrating a distribution of mounting angles of the semiconductor chip according to an exemplary embodiment in the present disclosure on a board.

Inventive Example may indicate the board having a semiconductor chip mounted thereon according to an exemplary embodiment in the present disclosure, and Comparative Example may indicate a board having a semiconductor chip mounted thereon in which scribe lines are not formed according to the related art.

Referring to FIGS. 10A and 10B, it may be appreciated that the numbers of samples of each of Inventive Example and Comparative Example are twenty, a distribution of mounting angles of Inventive Example is more excellent than that of mounting angles of Comparative Example with respect to the twenty samples and the mounting angles are distributed more closely to 0° in Inventive Example than in Comparative Example.

In addition, it may be appreciated that samples of Inventive Example have a mounting angle of 1.5° or less and a half or more of samples of Comparative Example have amounting angle of 1.5° or more.

In the case in which the mounting angle is 1.5° or more, the integrated circuit on the semiconductor chip and a wire may not smoothly contact each other in a wire-bonding process between the semiconductor chip and the printed circuit board, which may cause an influence such as a yield decrease, or the like.

As the mounting angle at the time of mounting the semiconductor chip on the printed circuit board becomes closer to 0°, quality and a yield may become higher in the wire-bonding process between the semiconductor chip and the printed circuit board after mounting the semiconductor chip on the printed circuit board.

In addition, since bonding reliability between the semiconductor chip and the solder becomes excellent by the semiconductor chip having the T-shape, stability in mounting the semiconductor chip on the printed circuit board may be secured.

Since the semiconductor chip is stably mounted on the printed circuit board, heat radiation characteristics of the semiconductor chip may be secured to some degree, and uniformity of current density of the semiconductor chip may be maintained.

As set forth above, according to exemplary embodiments in the present disclosure, the scribe lines may be formed in the semiconductor wafer to cut the semiconductor wafer. Therefore, the semiconductor chip having good quality may be manufactured.

In addition, with the semiconductor chip including the metal layer formed on the scribe lines and the board having the same mounted thereon, the bonding reliability between the semiconductor chip and the solder may be improved at the time of mounting the semiconductor chip on the solder.

While exemplary embodiments have been shown and described above, it will be apparent to those skilled in the art that modifications and variations could be made without departing from the scope of the invention as defined by the appended claims.

What is claimed is:

1. A semiconductor chip comprising:
a semiconductor body having scribe lines disposed on end surfaces thereof; and
a metal layer disposed on a lower surface of the semiconductor body and the scribe lines,
wherein an upper surface of the semiconductor body has a width greater than that of the lower surface thereof.

2. The semiconductor chip of claim 1, wherein the scribe lines is formed vertically from the lower surface of the semiconductor body.

3. The semiconductor chip of claim 1, wherein a ratio of a depth of the scribe lines to an overall thickness of the semiconductor body is in a range of 0.3 to 0.7.

4. The semiconductor chip of claim 1, wherein the scribe lines is formed from the lower surface of the semiconductor body into the semiconductor body.

5. The semiconductor chip of claim 1, wherein the metal layer has a thickness of 5 μm or less.

6. A board having a semiconductor chip mounted thereon, comprising:
a printed circuit board;
a semiconductor chip including a semiconductor body having scribe lines disposed on end surfaces thereof and a metal layer disposed on a lower surface of the semiconductor body and the scribe lines; and
a solder bonding part disposed on a surface of the printed circuit board and bonded to the metal layer,
wherein an upper surface of the semiconductor body has a width greater than that of the lower surface thereof.

7. The board having a semiconductor chip mounted thereon of claim 6, wherein in the case that a mounting angle of the semiconductor chip on the printed circuit board when the printed circuit board and the semiconductor chip are in parallel with each other is 0°, a mounting angle of the semiconductor chip on the printed circuit board is 1.5° or less.

8. The board having a semiconductor chip mounted thereon of claim 6, wherein a ratio of a depth of the scribe lines to an overall thickness of the semiconductor body is in a range of 0.3 to 0.7.

9. The board having a semiconductor chip mounted thereon of claim 6, wherein the scribe lines is formed from the lower surface of the semiconductor body into the semiconductor body.

10. The board having a semiconductor chip mounted thereon of claim 6, wherein the metal layer has a thickness of 5 μm or less.

11. A method of cutting a semiconductor wafer, comprising:
preparing a semiconductor wafer including scribe regions and semiconductor chip regions;
forming first scribe lines from a lower surface of the semiconductor wafer into the scribe regions;
forming a metal layer on the lower surface of the semiconductor wafer and the first scribe lines; and
forming second scribe lines from an upper surface of the semiconductor wafer into the scribe regions to cut the semiconductor wafer into a plurality of semiconductor chips.

12. The method of cutting a semiconductor wafer of claim 11, wherein in the case that a width of the first scribe lines is W1 and a width of the second scribe lines is W2, W1>W2 is satisfied.

13. The method of cutting a semiconductor wafer of claim 11, wherein in the case that a thickness of the semiconductor wafer is Ta and a thickness of the first scribe lines is T1, a ratio (T1/Ta) of the depth of the first scribe lines to the thickness of the semiconductor wafer is in a range of 0.3 to 0.7.

14. The method of cutting a semiconductor wafer of claim 11, wherein the first scribe lines is formed from the lower surface of the semiconductor wafer into the semiconductor chip region.

15. The method of cutting a semiconductor wafer of claim 11, wherein the metal layer has a thickness of 5 μm or less.
